(19) United States
(12) Patent Application Publication
(10) Pub. No.: US 2025/0175045 A1
(43) Pub. Date: May 29, 2025

(54) AXIAL GAP MOTOR, ROBOT, AND ROBOT SYSTEM

(71) Applicant: KABUSHIKI KAISHA YASKAWA DENKI, Fukuoka (JP)

(72) Inventors: Masanobu KAKIHARA, Fukuoka (JP); Yuki HONDA, Fukuoka (JP); Dai SHIMIZU, Fukuoka (JP); Yoshikazu MATSUMOTO, Fukuoka (JP); Daisuke MIYAZAKI, Fukuoka (JP)

(21) Appl. No.: 18/945,034

(22) Filed: Nov. 12, 2024

(30) Foreign Application Priority Data
Nov. 24, 2023 (JP) 2023-199450

(51) Int. Cl. H02K 1/2795; B25J 9/12; H01L 21/687; H02K 11/21; H02K 21/24; H02K 29/03

(52) U.S. Cl. CPC H02K 1/2795; B25J 9/126; H01L 21/68707; H02K 11/21; H02K 21/24; H02K 29/03; H02K 2201/06; H02K 2213/03

(57) ABSTRACT

An axial gap motor includes a rotor that rotates about a rotational axis, a stator that faces the rotor in a direction of the rotational axis, a back yoke provided on the rotor, and a plurality of magnets arranged on the back yoke along a circumferential direction around the rotational axis. The plurality of magnets include a plurality of first magnets arranged at an equal angular interval in the circumferential direction and a plurality of second magnets each arranged between the plurality of first magnets and arranged at a position shifted by a predetermined shift angle θ1 from a center angle of two adjacent first magnets in the circumferential direction.

### CROSS-REFERENCE TO RELATED APPLICATIONS

This application is based on and claims priority from Japanese Patent Application No. 2023-199450 filed on Nov. 24, 2023, with the Japan Patent Office, the disclosure of which is incorporated herein in its entirety by reference.

### TECHNICAL FIELD

Disclosed embodiments relate to an axial gap motor, a robot, and a robot system.

### BACKGROUND

Japanese Patent Application No. S58-222766 discloses a flat rotary electric machine in which a rotor and a stator are provided with an axial air gap therebetween. The flat rotary electric machine enables a smooth operation with a reduced cogging torque by giving a skewed shape to a permanent magnet forming a magnetic pole.

### SUMMARY

In the above related art, there are cases where a cogging torque is not sufficiently reduced, and that require a motor that may more effectively reduce the cogging torque.

The present disclosure provides an axial gap motor, a robot, and a robot system that may effectively reduce a cogging torque.

According to one aspect of the present disclosure, an axial gap motor includes a rotor that rotates about a rotational axis, a stator that faces the rotor in a direction of the rotational axis, a first back yoke provided on either the rotor or the stator, and a plurality of magnets arranged on the first back yoke along a circumferential direction around the rotational axis, wherein the plurality of magnets include a plurality of first magnets arranged at an equal angular interval in the circumferential direction, and a plurality of second magnets each arranged between the plurality of first magnets and arranged at a position shifted by a predetermined first angle from a center angle of two adjacent first magnets in the circumferential direction.

Further, according to another aspect of the present disclosure, there is provided a robot with an axial gap motor arranged at a joint, wherein the axial gap motor includes a rotor that rotates about a rotational axis, a stator that faces the rotor in a direction of the rotational axis, a first back yoke provided on either the rotor or the stator, and a plurality of magnets arranged on the first back yoke along a circumferential direction around the rotational axis, wherein the plurality of magnets include a plurality of first magnets arranged at an equal angular interval in the circumferential direction, and a plurality of second magnets each arranged between the plurality of first magnets and arranged at a position shifted by a predetermined first angle from a center angle of two adjacent first magnets in the circumferential direction.

Further, according to another aspect of the present disclosure, there is provided a robot system including the robot and a control device that controls an operation of the robot.

The axial gap motor of the present disclosure effectively reduces a cogging torque.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating an example of the overall configuration of a robot system, according to an embodiment.

FIG. 2 is a perspective view illustrating an example of the external configuration of a first motor unit and a second motor unit provided at a distal portion of a second arm.

FIG. 3 is an exploded perspective view illustrating an example of the internal configuration of the first motor unit.

FIG. 4 is an exploded perspective view illustrating an example of the internal configuration of the second motor unit.

FIG. 5 is a cross-sectional view schematically illustrating an example of the internal configuration of the first motor unit and the second motor unit.

FIG. 6 is a perspective view illustrating an example of the overall configuration of a rotor.

FIG. 7 is a plan view illustrating an example of the overall configuration of the rotor as seen from the stator side in the axial direction.

FIG. 8 is a plan view illustrating an example of the shape of a magnet provided in the rotor.

FIG. 9 is a plan view illustrating an example of a method of cutting out a plurality of magnets provided in the rotor from a magnet sheet.

FIG. 10 is a graph illustrating an example of a relationship between the cogging torque and the coefficient of a shift angle of the magnets.

FIG. 11 is a perspective view illustrating an example of the overall structure of a stator as seen from the coil side.

FIG. 12 is a perspective view illustrating an example of the overall configuration of the stator as seen from the connection board side.

FIG. 13 is a cross-sectional view illustrating an example of the overall configuration of the stator.

FIG. 14 is a perspective view illustrating an example of the configuration of a bobbin provided in the stator.

FIG. 15 is a plan view illustrating an example of the arrangement of the magnets of the rotor, according to an embodiment.

FIG. 16 is a plan view illustrating an example of the arrangement of the magnets of the rotor according to a modification in which the magnets do not have a skewed shape.

FIG. 17 is a plan view illustrating an example of the arrangement of the magnets of the rotor according to a modification in which radial outer side and inner side edges of the magnets are arc-shaped.

FIG. 18 is a plan view illustrating an example of the arrangement of the magnets of the rotor according to a modification in which radial outer side and inner side edges of the magnets are arc-shaped and the magnets do not have a skewed shape.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments will be described with reference to the drawings. In the embodiment, for the convenience of describing the configuration of a robot and others, a three-dimensional Cartesian coordinate system with X, Y and Z-axes may be used as appropriate. The Z-axis is positive in the upward vertical direction, the X-axis runs along the extending direction of an arm that supports a hand and is positive toward the distal side that supports the hand, and the Y-axis is orthogonal to both the X-axis and the Z-axis.

### (1. Overall Configuration of Robot System)

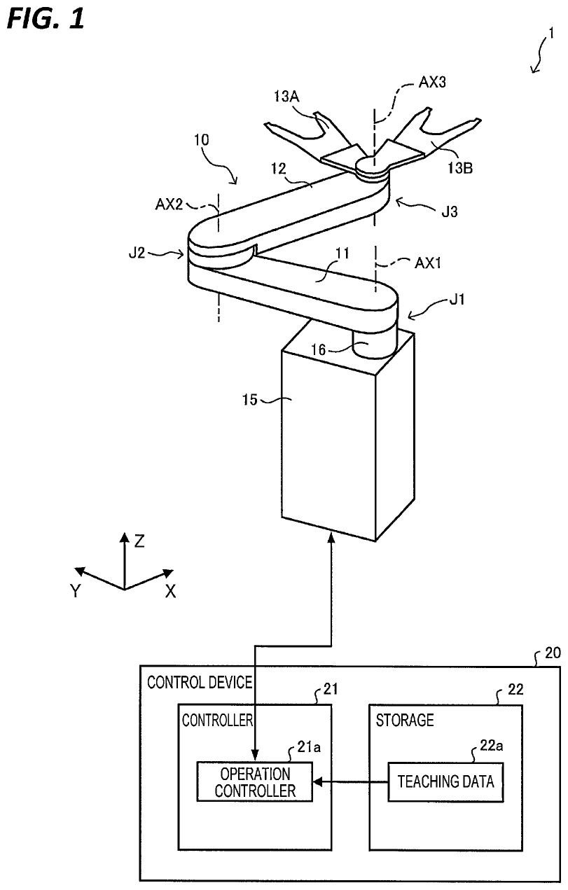

Referring to FIG. 1, an example of the overall configuration of a robot system 1, according to an embodiment, will be described. FIG. 1 is a diagram illustrating an example of the overall configuration of the robot system 1, according to an embodiment.

As illustrated in FIG. 1, the robot system 1 includes a transfer robot 10 and a control device 20 that controls the operation of the robot 10. The transfer robot 10 (e.g., a robot) includes a main body 15 installed on a floor and a lifter 16 that moves up and down relative to the main body 15. The lifter 16 moves a first arm 11 and a second arm 12, which constitute a horizontal multi-joint arm, up and down. For example, two hands 13A and 13B are attached to the distal side of the second arm 12. The hands 13A and 13B are each capable of holding a transfer target object such as a semiconductor substrate. The transfer robot 10 includes, for example, three joints J1, J2 and J3. At the joint J1, the first arm 11 pivots around a motor rotational axis AX1 relative to the lifter 16. At the joint J2, the second arm 12 pivots around a motor rotational axis AX2 relative to a distal end of the first arm 11. At the joint J3, the hands 13A and 13B each pivot coaxially around a motor rotational axis AX3. The rotational axes AX1, AX2 and AX3 are approximately parallel to the Z axis.

In addition, although two hands 13A and 13B are illustrated in FIG. 1, the number of hands may be three or more. Further, the horizontal multi-joint arm is constituted with two arms (e.g., first arm 11 and second arm 12) in FIG. 1, but the present disclosure is not limited thereto and may include one arm, or three or more arms.

The control device 20 is connected to the transfer robot 10. The control device 20 includes a controller 21 and a storage 22. The controller 21 includes an operation controller 21a. Further, the storage 22 stores teaching data 22a.

The operation controller 21a controls the operation of the transfer robot 10 based on the teaching data 22a. As an example, the operation controller 21a instructs a motor corresponding to each axis in the transfer robot 10 based on the teaching data 22a stored in the storage 22, thereby enabling the transfer robot 10 to transfer the transfer target object such as a substrate. The operation controller 21a performs a feedback control using detection values of an encoder in the motor. The operation controller 21a may also stop or decelerate the operation of the transfer robot 10, for example, in the event of an error in the operation of the transfer robot 10.

The teaching data 22a is generated through the teaching that teaches the transfer robot 10 for an operation. The teaching data 22a is information that defines the operation of the transfer robot 10 such as the movement trajectory of the hand. In addition, the teaching data 22a generated by other computers connected via a wired or wireless network may be stored in the storage 22.

### (2. Configuration of Motor Unit)

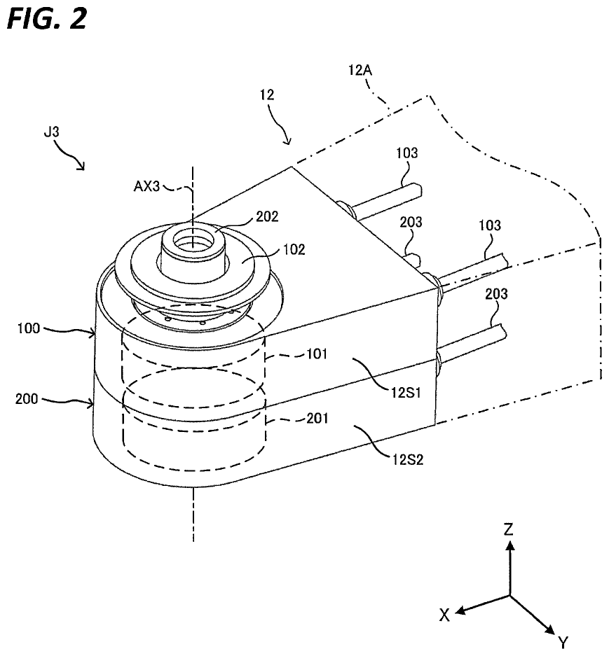

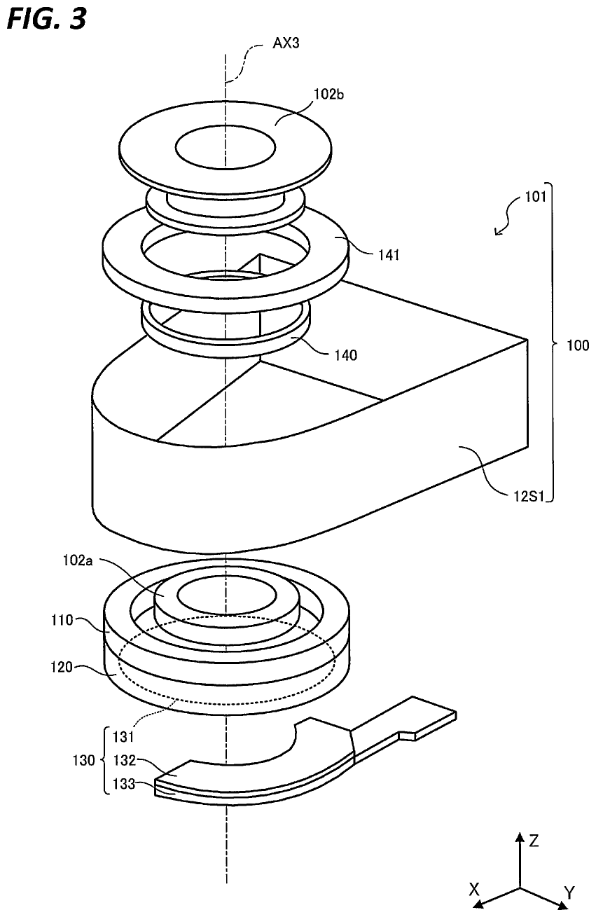

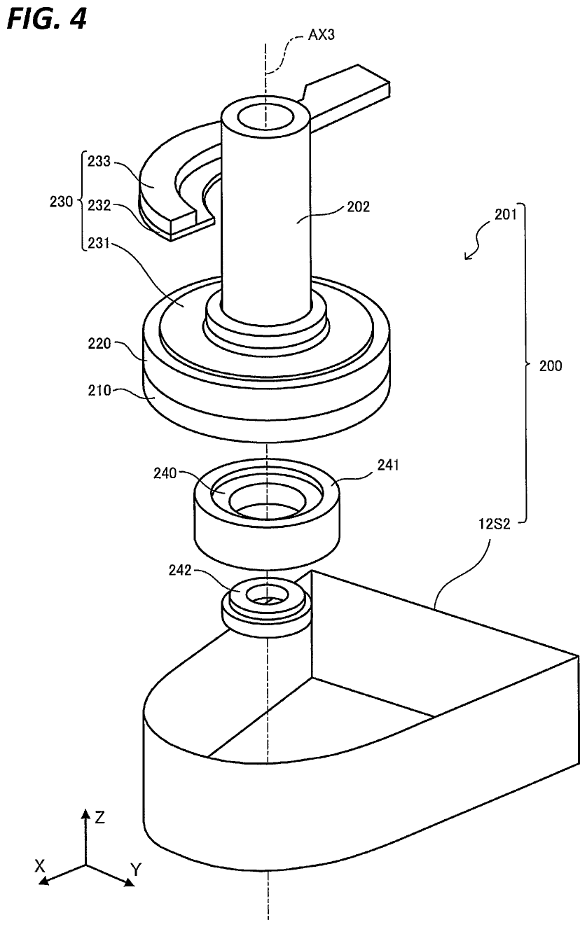

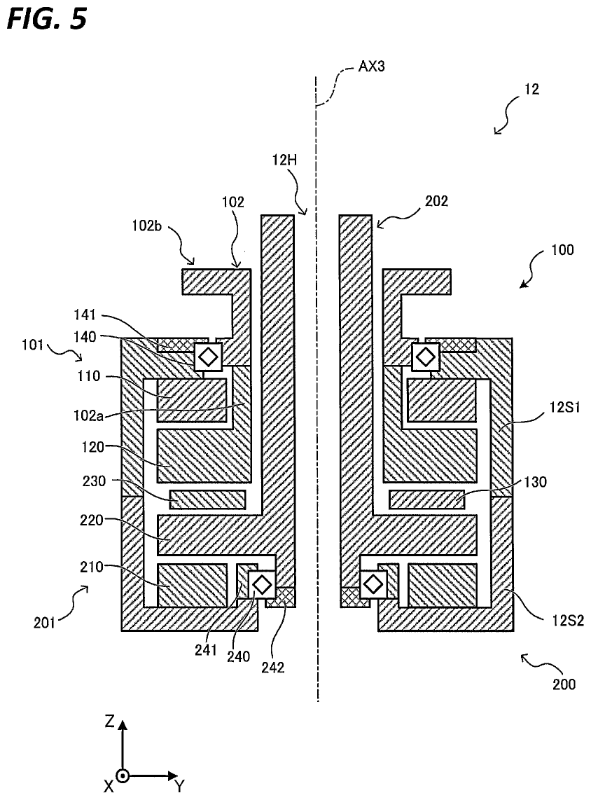

Referring to FIGS. 2 to 5, an example of the configuration of a motor unit for driving the hands provided at the joint J3 of the transfer robot 10 will be described. FIG. 2 is a perspective view illustrating an example of the external configuration of a first motor unit and a second motor unit provided at a distal portion of the second arm. FIG. 3 is an exploded perspective view illustrating an example of the internal configuration of the first motor unit, and FIG. 4 is an exploded perspective view illustrating an example of the internal configuration of the second motor unit. FIG. 5 is a cross-sectional view schematically illustrating an example of the internal configuration of the first motor unit and the second motor unit. In addition, FIG. 5 corresponds to a cross-sectional view taken along a plane parallel to the YZ plane at the position of the rotational axis AX3, when viewed from the distal side to the proximal side of the second arm 12.

As illustrated in FIG. 2, a first motor unit 100 and a second motor unit 200 are provided at the distal side of a base frame 12A of the second arm 12 to drive the two hands 13A and 13B, respectively. The first motor unit 100 and the second motor unit 200 are arranged to overlap each other in the direction along the rotational axis AX3, and in the example illustrated in FIG. 2, the first motor unit 100 is located above the second motor unit 200. The first motor unit 100 includes a subframe 12S1 and a first motor 101 built into the subframe 12S1. The second motor unit 200 includes a subframe 12S2 and a second motor 201 built into the subframe 12S2. The base frame 12A and the subframes 12S1 and 12S2 constitute a case of the second arm 12. In addition, in FIG. 2, the base frame 12A is illustrated by a one-dot dashed line.

The first motor 101 and the second motor 201 are arranged in an alignment posture in the direction along the rotational axis AX3 as a common axis. The first motor 101 drives the hand 13A, and the second motor 201 drives the hand 13B. Each of the first motor 101 and the second motor 201 is a so-called axial gap motor in which a rotor and a stator face each other in the direction along the rotational axis AX3. The first motor 101 and the second motor 201 directly drive the hands 13A and 13B, respectively.

The first motor 101 and the second motor 201 are so-called hollow motors in which a hollow region is formed to extend along the rotational axis AX3. The first motor 101 includes a hollow shaft 102, and the second motor 201 includes a hollow shaft 202. The hollow shaft 102 is connected to a rotor 120 (see, e.g., FIGS. 3 and 5 to be described later) of the first motor 101, and the hollow shaft 202 is connected to a rotor 220 (see, e.g., FIGS. 4 and 5 to be described later) of the second motor 201. The hollow shafts 102 and 202 extend along the rotational axis AX3 and rotate around the rotational axis AX3.

As illustrated in FIG. 2, the hollow shaft 102 of the first motor 101 protrudes toward an upper surface of the subframe 12S1 of the first motor unit 100. The hollow shaft 202 of the second motor 201 is inserted through the hollow shaft 102 of the first motor 101, passes through the first motor unit 100, and protrudes toward the upper surface of the subframe 12S1. The hand 13A is connected to the hollow shaft 102, and the hand 13B is connected to the hollow shaft 202. The inner hollow shaft 202 pivots the upper hand 13B, and the outer hollow shaft 102 pivots the lower hand 13A.

In addition, when there are three or more hands, the same number of motor units as the hands may be provided.

As illustrated in FIG. 3, the first motor unit 100 includes the first motor 101 and the subframe 12S1. In addition, FIG. 3 omits the illustrations of components such as a cover that is detachably attached to the upper surface of the subframe 12S1, a communication hole that is formed in a side surface of the subframe 12S1 connected to the base frame 12A for passing a cable 103 (see, e.g., FIG. 2) therethrough, and an inner wall that is formed in the inside of the subframe 12S1 for the attachment of each component of the first motor 101.

The first motor 101 (e.g., an axial gap motor) includes the rotor 120 that rotates about the rotational axis AX3 and a stator 110 that faces the rotor 120 in the direction of the rotational axis AX3. The first motor 101 includes a shaft portion 102a and a boss portion 102b, which constitute the hollow shaft 102 illustrated in FIG. 2, a bearing 140, and a bearing retainer 141. The first motor 101 includes an encoder 130. The encoder 130 includes a disk 131, a detector 132, and a support 133.

The stator 110 has a disc shape with a hollow region along the rotational axis AX3, and is provided with teeth on an end surface thereof toward the rotor 120 and a coil wound around the teeth. In addition, a detailed structure of the stator 110 will be described later. The rotor 120 has a disk shape with a hollow region along the rotational axis AX3, which communicates with the hollow region of the stator 110, and is provided with a plurality of magnets along the circumferential direction on an end surface thereof toward the stator 110. In addition, a detailed structure of the rotor 120 will be described later. The disk 131 of the encoder 130 is fixed to an end surface of the rotor 120 opposite to the stator 110. The disk 131 also has a hollow region communicating with the hollow region of the rotor 120.

The shaft portion 102a of the hollow shaft 102 is fixed to an upper surface of the rotor 120. The stator 110 is arranged such that the inner periphery thereof is spaced apart from the outer periphery of the shaft portion 102a. The bearing 140 is a so-called cross roller bearing. The inner peripheral side of the bearing 140 is fixed to the outer periphery of the boss portion 102b of the hollow shaft 102, and the outer peripheral side of the bearing 140 is fixed to the subframe 12S1 by the bearing retainer 141. In addition, FIG. 3 omits the illustration of an inner wall of the subframe 12S1 to which the bearing 140 is fixed. The boss portion 102b of the hollow shaft 102 is fixed to an upper surface of the shaft portion 102a so that a hollow region thereof communicates with a hollow region of the shaft portion 102a.

The detector 132 of the encoder 130 is arranged to face the disk 131 provided on the end surface of the rotor 120. The support 133 supports an end surface of the detector 132 opposite to the disk 131 and is fixed to the subframe 12S1. In addition, the support 133 may be shaped to be fixable to the stator 110 and may be fixed to the stator 110.

As illustrated in FIG. 4, the second motor unit 200 includes the second motor 201 and the subframe 12S2. In addition, FIG. 4 omits the illustrations of components such as a communication hole that is formed in a side surface of the subframe 12S2 connected to the base frame 12A for passing a cable 203 (see, e.g., FIG. 2) therethrough and an inner wall that is formed in the inside of the subframe 12S2 for the attachment of each component of the second motor 201.

The second motor 201 (e.g., an axial gap motor) includes the rotor 220 that rotates about the rotational axis AX3 and a stator 210 that faces the rotor 220 in the direction of the rotational axis AX3. The second motor 201 includes the hollow shaft 202 illustrated in FIG. 2, a bearing 240, an outer peripheral retainer 241, and an inner peripheral retainer 242. The outer peripheral retainer 241 is a component that presses the outer periphery of the bearing 240, and the inner peripheral retainer 242 is a component that presses the inner periphery of the bearing 240. The second motor 201 includes an encoder 230. The encoder 230 includes a disk 231, a detector 232, and a support 233.

The stator 210 has a disc shape with a hollow region along the rotational axis AX3, and is provided with teeth on an end surface thereof toward the rotor 220 and a coil wound around the teeth. In addition, a detailed structure of the stator 210 will be described later. The rotor 220 has a disk shape with a hollow region along the rotational axis AX3, which communicates with the hollow region of the stator 210, and is provided with a plurality of magnets along the circumferential direction on an end surface toward the stator 210. In addition, a detailed structure of the rotor 220 will be described later. The disk 231 of the encoder 230 is fixed to an end surface of the rotor 220 opposite to the stator 210. The disk 231 is formed with a hollow region through which the hollow shaft 202 passes.

The hollow shaft 202 is fixed to an upper surface of the rotor 220. The bearing 240 is a so-called cross roller bearing. The inner peripheral side of the bearing 240 is fixed to the outer periphery of the hollow shaft 242 by the inner peripheral retainer 242, and the outer peripheral side of the bearing 240 is fixed to the subframe 12S2 by the outer peripheral retainer 241.

The detector 232 of the encoder 230 is arranged to face the disk 231 provided on the end surface of the rotor 220. The support 233 supports an end surface of the detector 232 opposite to the disk 231 and is fixed to the subframe 12S2. In addition, the support 233 may be shaped to be fixable to the stator 210 and may be fixed to the stator 210.

Next, the second arm 12 in which the first motor unit 100 illustrated in FIG. 3 and the second motor unit 200 illustrated in FIG. 4 have been assembled, will be described with reference to FIG. 5.

As illustrated in FIG. 5, the boss portion 102b of the hollow shaft 102 of the first motor unit 100 protrudes upward from an upper surface of the second arm 12. The hollow shaft 202 of the second motor unit 200 passes through the hollow shaft 102 of the first motor unit 100 and protrudes upward from the upper surface of the second arm 12.

The respective components of the first motor 101 and the second motor 201 are arranged along the rotational axis AX3 in the order of the stator 210 of the second motor 201, the rotor 220 of the second motor 201, the rotor 120 of the first motor 101, and the stator 110 of the first motor 101 from the bottom to the top of the second arm 12.

The encoder 130 of the first motor unit 100 is positioned to face the bottom of the rotor 120 in the first motor unit 100, and the encoder 230 of the second motor unit 200 is positioned to face the top of the rotor 220 in the second motor unit 200. As illustrated in FIG. 5, the encoders 130 and 230 are arranged at approximately the same height in the direction along the rotational axis AX3.

As illustrated in FIG. 5, the first motor 101 and the second motor 201 have a hollow region 12H that penetrates from the bottom to the top of the second arm 12 along the rotational axis AX3. Cables such as a cable for the hand 13B connected to the hollow shaft 202 of the second motor unit 200 may be routed in the hollow region 12H.

### (3. Configuration of Rotor)

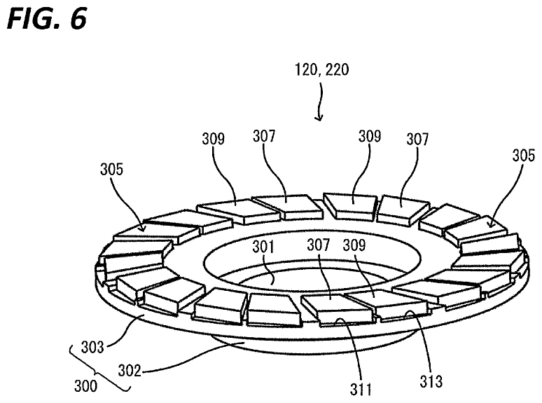

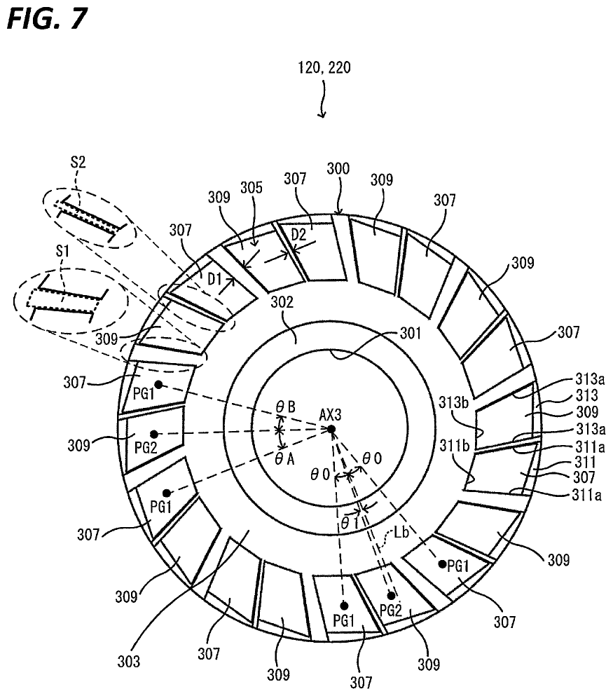

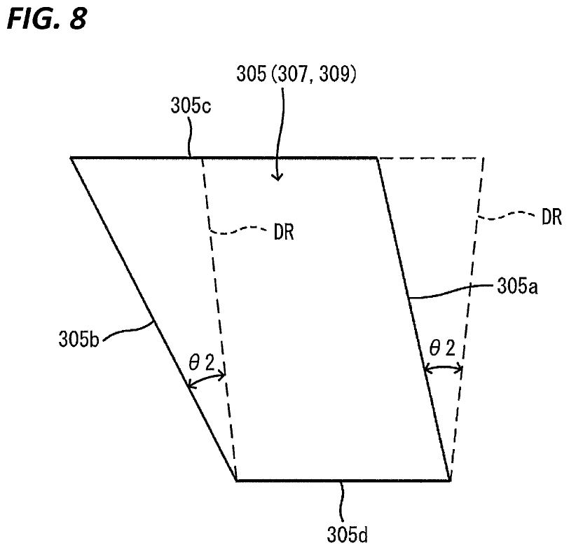

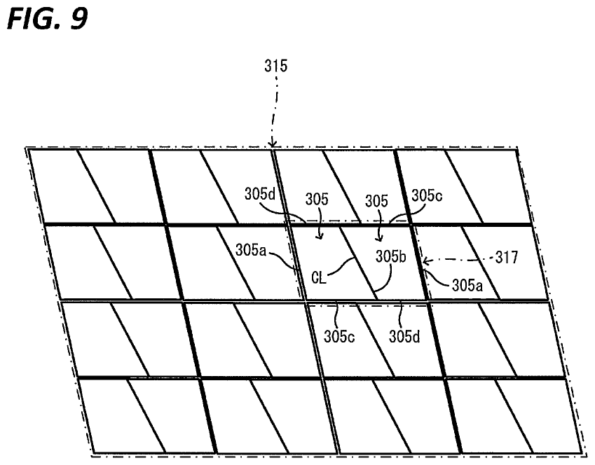

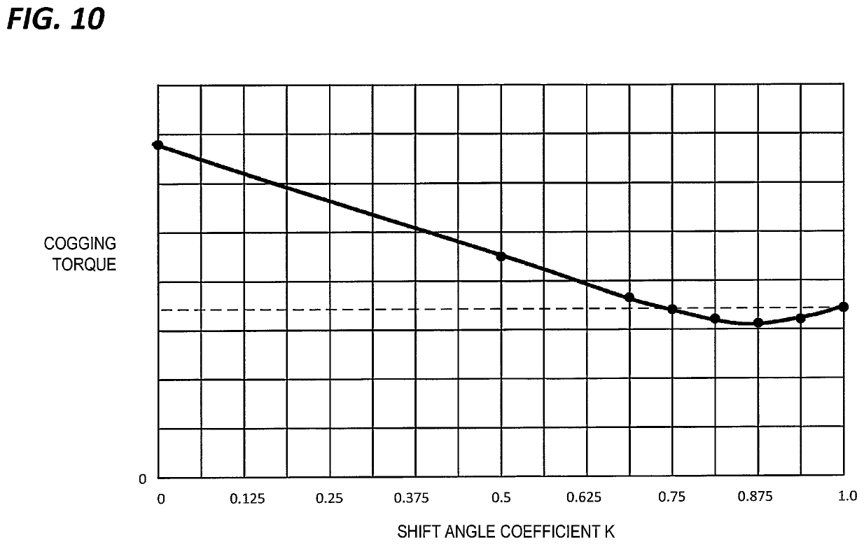

Referring to FIGS. 6 to 10, an example of the configurations of the rotor 120 of the first motor 101 and the rotor 220 of the second motor 201 will be described. The rotors 120 and 220 have a common configuration. FIG. 6 is a perspective view illustrating an example of the overall configuration of the rotors 120 and 220, FIG. 7 is a plan view illustrating an example of the overall configuration of the rotors 120 and 220 as seen from the stator side in the axial direction, FIG. 8 is a plan view illustrating an example of the shape of magnets provided in the rotors 120 and 220, FIG. 9 is a plan view illustrating an example of a method of cutting out the magnets provided in the rotors 120 and 220 from a plate-shaped magnet sheet, and FIG. 10 is a graph illustrating an example of a relationship between the cogging torque and the coefficient of a shift angle of the magnets. In addition, in the description of FIGS. 6 to 10, the term “circumferential direction” refers to the direction around the circumference centered on the rotational axis AX3, and the term “radial direction” refers to the direction along the radius centered on the rotational axis AX3.

As illustrated in FIGS. 6 and 7, the rotors 120 and 220 each include an annular rotor core 300. The rotor core 300 centrally has a cylindrical hollow region 301 extending along the rotational axis AX3. The rotor core 300 includes a hub portion 302 connected to the above-described shaft portion 102a and a back yoke portion 303 (e.g., a first back yoke) having a surface for the arrangement of magnets. The rotor core 300 is made of a magnetic material. A plurality of magnets 305 are arranged on the surface of the back yoke portion 303 facing the stator 110 or the stator 210 in the circumferential direction around the rotational axis AX3. In the present embodiment, a case where the number of magnets 305 is 20 (e.g., 20 poles) is described as an example, but the number of magnets 305 may be different from twenty (20). The plurality of magnets 305 include a plurality of (e.g., half the number of magnets 305) first magnets 307, which are arranged at equal angular intervals in the circumferential direction, and a plurality of (e.g., half the number of magnets 305) second magnets 309, which are arranged at equal angular intervals in the circumferential direction, each placed alternately with the first magnets 307. Each second magnet 309 is arranged between the first magnets 307 and is arranged at a position shifted by a predetermined shift angle θ1 (e.g., a first angle) from the center angle of two adjacent first magnets 307 in the circumferential direction (the center position between two first magnets 307 adjacent in the circumferential direction expressed as an angle in the circumferential direction). The first magnets 307 and the second magnets 309 have the same shape. According to an embodiment, the plurality of magnets 305 each have the same shape. In addition, in the present embodiment, when it is not necessary to distinguish between the first magnets 307 and the second magnets 309, they are collectively referred to as the magnets 305.

In addition, when describing the arrangement of each magnet in the present embodiment, the reference position may be, for example, any consistently determined reference position such as the position of the center of gravity of the magnet, the position of either one circumferential end or the other circumferential end, or the position of either one radial end or the other radial end. In the present embodiment, for example, the position of the center of gravity of the magnet is used as the reference position. Specifically, as illustrated in FIG. 7, the position of the center of gravity PG2 of the second magnet 309 is at an angle shifted by the shift angle θ1 in the circumferential direction (e.g., clockwise in FIG. 7) from a bisector line Lb of an angle 200 between the positions of the center of gravity PG1 of two circumferentially adjacent first magnets 307 and is also at the same radial distance from the rotational axis AX3 as the position of the center of gravity PG1.

In addition, the arrangement of the plurality of magnets 305 may be described as follows. As illustrated in FIG. 7, the plurality of magnets 305 are arranged at unequal intervals such that the interval between two circumferentially adjacent magnets 305 repeatedly alternates in the circumferential direction between a first interval D1 and a second interval D2, which is smaller than the first interval D1. In addition, the first interval D1 and the second interval D2 are intervals between the same positions of the magnets taken in the radial direction from the rotational axis AX3, such as the position of the center of gravity of the magnet, or the position of either one radial end or the other radial end.

Further, the arrangement of the plurality of magnets 305 may be described as follows. As illustrated in FIG. 7, the plurality of magnets 305 are arranged at unequal intervals such that the angle between two circumferentially adjacent magnets 305 repeatedly alternates in the circumferential direction between a first angle θA and a second angle θB, which is smaller than the first angle θA. In addition, the reference position for the angle between the magnets may be any consistently determined reference position such as the position of the center of gravity of the magnet, or the position of either one circumferential end or the other circumferential end. In the present embodiment, as illustrated in FIG. 7, the angle is based on the positions of the center of gravity PG1 and PG2 of the magnets.

As a result of the plurality of magnets 305 being arranged as described above, different gap shapes between the first magnets 307 and the second magnets 309 alternate in the circumferential direction. As illustrated in the partially enlarged view of FIG. 7, a gap shape S1 and a gap shape S2, which are adjacent in the circumferential direction, are mutually dissimilar, and do not match even when rotated around the rotational axis AX3. In addition, in FIG. 7, the gap shapes S1 and S2 are depicted as the shape of extending the space between the first magnet 307 and the second magnet 309 to the outer periphery of the back yoke portion 303, but the same applies when they are depicted as only the shape of the space between the first magnet 307 and the second magnet 309.

As illustrated in FIGS. 6 and 7, a first recess 311 for accommodating the first magnet 307 and a second recess 313 for accommodating the second magnet 309 are formed in the surface of the back yoke portion 303 where the magnets 305 are arranged. The first recess 311 is shaped to correspond to the first magnet 307, and the first magnet 307 is fixed, for example, by adhesion. As illustrated in FIG. 7, the first magnet 307 is circumferentially positioned by having at least one of one circumferential end and the other circumferential end of the first magnet 307 abut against a stepped portion 311a of the first recess 311 on either one circumferential side or the other circumferential side. Further, the first magnet 307 is radially positioned by having the radial inner end of the first magnet 307 abut against a stepped portion 311b of the first recess 311 on the radial inner side.

The second recess 313 is shaped to correspond to the second magnet 309, and the second magnet 309 is fixed, for example, by adhesion. The second magnet 309 is circumferentially positioned by having at least one of one circumferential end and the other circumferential end of the second magnet 309 abut against a stepped portion 313a of the second recess 313 on either one circumferential side or the other circumferential side. Further, the second magnet 309 is radially positioned by having the radial inner end of the second magnet 309 abut against a stepped portion 313b of the second recess 313 on the radial inner side.

FIG. 8 illustrates an example of the shape of the magnets 305 (e.g., first magnets 307 and second magnets 309). As illustrated in FIG. 8, the magnets 305 have a so-called skewed shape, in which one side edge 305a and the other side edge 305b in the circumferential direction are inclined by a predetermined skew angle θ2 (e.g., a second angle) in the same direction with respect to the radial direction DR centered on the rotational axis AX3. Further, the magnet 305 is shaped such that an outer side edge 305c and an inner side edge 305d are straight and parallel in the radial direction. In an embodiment, the magnets 305 have a trapezoidal shape in which one pair of edges 305c and 305d are parallel and the other pair of edges 305a and 305b are not parallel.

FIG. 9 illustrates an example of a method of cutting out a plurality of magnets 305 from a magnet sheet. As illustrated in FIG. 9, the plurality of (e.g., 32) magnets 305 are manufactured from a parallelogram plate-shaped magnet sheet 315. The parallelogram of the magnet sheet 315 is similar to a parallelogram (e.g., the shape of division sheet 317) formed by arranging a pair of magnets 305 and 305 such that the edges 305b face each other and the edges 305c and 305d are crossed diagonally. By equally dividing the magnet sheet 315 into a plurality of sections in the vertical and horizontal directions, a plurality of (e.g., 16) parallelogram division sheets 317 are formed, each having a shape similar to the parallelogram of the magnet sheet 315. Furthermore, by bisecting the division sheet 317 in the longitudinal direction along a cutting line CL inclined relative to both the longitudinal edges 305a, the pair of magnets 305 are formed. With this cutting method, it is possible to prevent an excess material from being generated in the magnet sheet 315, allowing the magnets 305 to be cut out efficiently without waste.

FIG. 10 illustrates an example of a relationship between the cogging torque generated in the rotors 120 and 220 and the coefficient K of the shift angle θ1 of the second magnets 309. The shift angle θ1 is represented by the following Equation (1) where LCM is the least common multiple of the number of slots in the stators 110 and 210 and the number of poles in the rotors 120 and 220, and K is the coefficient. The number of slots is the number of teeth in the stator 110 or the stator 210, and the number of poles is the number of magnets 305 in the rotor 120 or the rotor 220. FIG. 10 illustrates the magnitude of the cogging torque when changing the coefficient K from 0 to 1.0.

$$θ 1 = K \times \{ ( 360 ° / L C M ) / 2 \} \qquad Equation ( 1 )$$

For example, when the number of slots in the stators 110 and 210 is twenty-four (24) and the number of poles in the rotors 120 and 220 is twenty (20), the least common multiple (LCM) is one hundred twenty (120). In addition, the LCM may be six times or more than the number of poles in the rotors 120 and 220. For example, increasing the skew angle θ2 of the magnets 305 increases the effect of reducing the cogging torque, but depending on the slot combination of the motor, it may be difficult to arrange the plurality of magnets 305 at unequal intervals. In that case, it is possible to reduce the size of the magnets 305 for such an arrangement, but this will result in a decrease in the output torque of the motor. When the LCM is set to six times or more than the number of poles, the shift angle θ1 may be reduced according to the above Equation (1). This makes it possible to simultaneously apply both the relatively large skew angle θ2 and the unequal interval arrangement of the magnets 305, while minimizing a reduction in the size of the magnets 305.

One cycle of the waveform of the cogging torque generated in the rotors 120 and 220 is represented by “360°/LCM.” Therefore, by setting the shift angle θ1 of the second magnets 309 to half of the one cycle of the cogging torque waveform, which is {(360°/LCM)/2}, e.g., the coefficient K=1.0 in Equation (1), the cogging torque may be reduced compared to a case where the shift angle θ1 is set to zero (0) degrees (when K=0), as illustrated in FIG. 10.

In addition, as illustrated in FIG. 10, when changing the coefficient K from 0 to 1.0, for example, changing the shift angle θ1 from 0 degrees to {(360°/LCM)/2}, which is half of the one cycle of the cogging torque waveform, the cogging torque gradually decreases and reaches the lowest value when the coefficient K is less than 1.0, not at K=1.0. This is considered to be due to the following factors.

In general, in an axial gap motor with an open slot structure, the entire surface of the rotor magnet is not covered by the stator teeth (e.g., stator iron core), leading to a significant variation in magnetic path permeance through the rotor magnet and the stator teeth, which is one factor of increasing the cogging torque. While shifting the arrangement position of the second magnets 309 by the shift angle θ1, as in the present embodiment, may reduce the cogging torque, the arrangement position of the second magnets 309 may introduce manufacturing errors that may cause an imbalance in the forces acting on each magnet due to the permeance variation, potentially increasing the cogging torque. To address this, in the present embodiment, the first magnets 307 and the second magnets 309 have a skewed shape inclined by the skew angle θ2, as described above. This skewed shape allows the first magnets 307 and the second magnets 309 to bridge adjacent teeth of the opposing stator, helping to mitigate the force due to the permeance variation. Therefore, shifting the arrangement position of the second magnets 309 by the shift angle θ1 becomes practically feasible.

In the meantime, when the first magnets 307 and the second magnets 309 have a skewed shape, there may be cases where a high-frequency component (e.g., 4th and 6th components) of the cogging torque becomes significant due to an imbalance in the circumferential direction of the magnet shape and other factors. As described above, setting the coefficient K=1.0, e.g., setting the shift angle θ1 of the second magnets 309 to half of the one cycle of the cogging torque waveform {(360°/LCM)/2}, may reduce the fundamental component of the cogging torque. However, setting the coefficient K to be less than 1.0, e.g., setting the shift angle θ1 to be less than {(360°/LCM)/2}, is considered to effectively reduce not only the fundamental component, but also the high-frequency component of the cogging torque.

Based on the above, by setting the coefficient K to 1.0 or less, e.g., setting the shift angle θ1 to be equal to or less than {(360°/LCM)/2} as described in the following Equation (2), the cogging torque may be effectively reduced in response to both a case where the cogging torque mainly contains a fundamental component and a case where the cogging torque contains a harmonic component in addition to a fundamental component.

$$θ 1 \leq ( 360 ° / L C M ) / 2 \qquad Equation ( 2 )$$

Further, by setting the coefficient K to be less than 1.0, e.g., setting the shift angle θ1 to be less than {(360°/LCM)/2} as described in the following Equation (3), the cogging torque may be effectively reduced, particularly, in response to a case where the cogging torque contains a harmonic component.

$$θ 1 < ( 360 ° / L C M ) / 2 \qquad Equation ( 3 )$$

Further, as illustrated in FIG. 10, the value of the cogging torque for the coefficient K=1.0 may be approximately the same as the value of the cogging torque for the coefficient K=0.75. The value of the cogging torque for the coefficient K within the range of 0.75 to 1.0 may be equal to or less than the value of the cogging torque for the coefficient K=1.0 (e.g., when the shift angle θ1 is {(360°/LCM)/2}). Therefore, the cogging torque may be appropriately reduced by setting the coefficient K to 0.75 or more, which means setting the shift angle θ1 to 0.75×{(360°/LCM)/2} or more as described in the following Equation (4).

$$θ 1 \geq 0.75 \times \{ ( 360 ° / L C M ) / 2 \} \qquad Equation ( 4 )$$

Further, as illustrated in FIG. 10, the value of the cogging torque reaches the lowest value when the coefficient K is near 0.875. Therefore, setting the coefficient K to be near 0.875, which means setting the shift angle θ1 to be near 0.875×{(360°/LCM)/2} as described in the following Equation (5), allows for a more effective reduction in both fundamental and high-frequency components of the cogging torque.

$$θ1 \approx 0.875 \times \{ ( 360 ° / L C M ) / 2 \} \qquad Equation ( 5 )$$

In addition, the above term “near” means that the coefficient K or the shift angle θ1 may vary within a certain range as long as it significantly reduces the value of the cogging torque compared to that when the coefficient K=1.0.

In addition, the above description assumes that the first magnets 307 and the second magnets 309 have the same shape (e.g., all of the plurality of magnets 305 have the same shape), but the present disclosure is not limited to this. The first magnets 307 and the second magnets 309 may have different shapes, meaning that the plurality of magnets 305 may have different shapes from each other. In this case, the graph in FIG. 10 will change, and the value of the cogging torque for the coefficient K less than 0.75 may be equal to or less than that for the coefficient K=1.0.

### (4. Configuration of Stator)

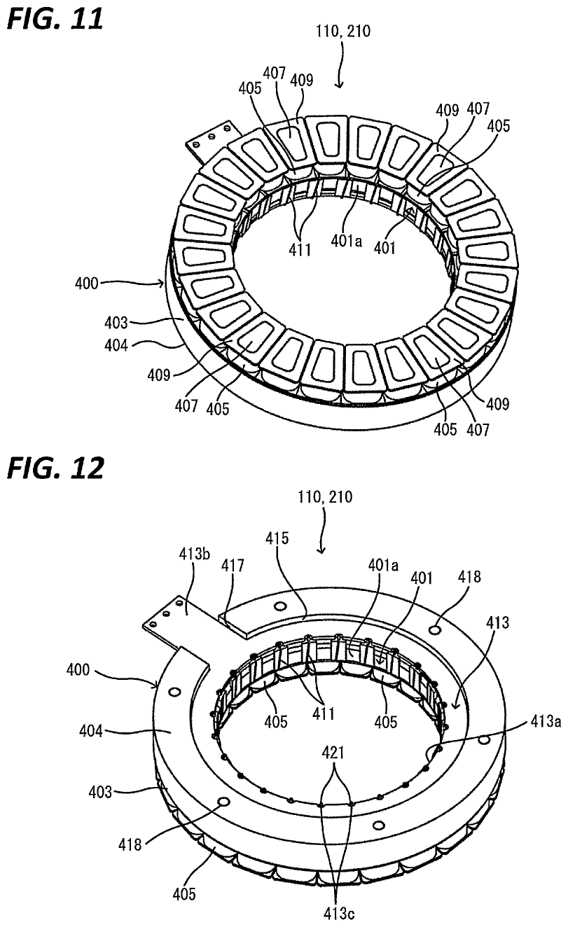

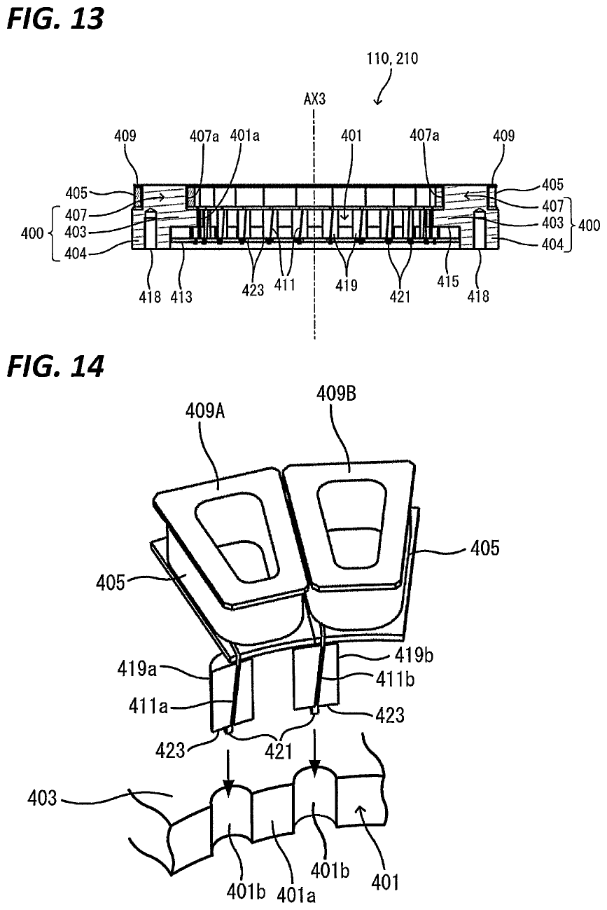

Referring to FIGS. 11 to 14, an example of the configuration of the stator 110 of the first motor 101 and the stator 210 of the second motor 201 will be described. The stators 110 and 210 have a common configuration. FIG. 11 is a perspective view illustrating an example of the overall configuration of the stators 110 and 210 as seen from the coil side, FIG. 12 is a perspective view illustrating an example of the overall configuration of the stators 110 and 210, as seen from the connection board side, FIG. 13 is a cross-sectional view illustrating an example of the overall configuration of the stators 110 and 210, and FIG. 14 is a perspective view illustrating an example of the configuration of a bobbin provided in the stators 110 and 210. In addition, in the description of FIGS. 11 to 14, the term “circumferential direction” refers to the direction around the circumference centered on the rotational axis AX3, and the term “radial direction” refers to the direction along the radius centered on the rotational axis AX3.

As illustrated in FIGS. 11 to 13, the stators 110 and 210 each include an annular stator core 400. The stator core 400 centrally has a cylindrical opening 401 extending along the rotational axis AX3. The stator core 400 includes an annular back yoke portion 403 (an example of a second back yoke), a plurality of teeth 407 each equipped with a coil 405, and an outer peripheral protruding portion 404 in which a connection board 413 is radially inwardly accommodated. The stator core 400 is made of a magnetic material. A plurality of coils 405 are arranged on a surface of the back yoke portion 403 facing the rotor 120 or the rotor 220. Specifically, as illustrated in FIGS. 11 and 13, the plurality of teeth 407 protrude from the back yoke portion 403 toward one side (e.g., upper side in FIG. 13) in the direction of the rotational axis AX3. Each of the plurality of teeth 407 is equipped with a cylindrical bobbin 409 with the coil 405 wound around an outer peripheral surface thereof. The bobbin 409 is made of an insulating material. The present embodiment describes a case where the number of coils 405, e.g., the number of teeth 407 is twenty-four (24) (e.g., 24 slots) as an example, but the number of coils 405 may be different from twenty-four (24).

As illustrated in FIGS. 12 and 13, the connection board 413 (e.g., a connector), which connects a plurality of lead wires 411 drawn out from the plurality of coils 405, is provided on the other side (e.g., lower side in FIG. 13) of the back yoke portion 403 in the direction of the rotational axis AX3. The connection board 413 is a ring-shaped board in which a circular opening 413a is radially inwardly formed to communicate with the opening 401 of the back yoke portion 403. A predetermined connection pattern is formed on a surface of the connection board 413 to connect the plurality of lead wires 411. The stator core 400 has a ring-shaped recess 415 on the other side (lower side in FIG. 13) in the direction of the rotational axis AX3, and the connection board 413 is accommodated in the recess 415. In addition, the connector for connecting the plurality of lead wires 411 may be in a form other than a board.

The outer peripheral protruding portion 404 is an approximately C-shaped protruding portion that protrudes from the outer periphery of the back yoke portion 403 toward the other side (e.g., lower side in FIG. 13) in the direction of the rotational axis AX3. By having the outer peripheral protruding portion 404 formed to protrude from the back yoke portion 403, the stator core 400 (e.g., back yoke portion 403) is configured to be thick at the outer periphery where the outer peripheral protruding portion 404 is formed and to be thin at the inner periphery inside the outer peripheral protruding portion 404. The recess 415 is an area that is located on the inner side of the outer peripheral protruding portion 404 in the radial direction and is surrounded by the outer peripheral protruding portion 404.

As illustrated in FIG. 12, the connection board 413 has a terminal portion 413b, which protrudes radially outward at a part of the circumference, and a power cable and others are connected to the terminal portion 413b. The outer peripheral protruding portion 404 has a notch 417 extending in the radial direction at a part of the circumference, and the terminal portion 413b of the connection board 413 is accommodated in the notch 417. By fitting the terminal portion 413b into the notch 417, the connection board 413 is positioned in the circumferential (angular) direction, which prevents any circumferential misalignment.

As illustrated in FIG. 12, the outer peripheral protruding portion 404 is formed with a plurality of (e.g., 6) bolt holes 418 for fixing the stator core 400 to the above-described subframes 12S1 and 12S2. The plurality of bolt holes 418 are arranged in the circumferential direction at, for example, equal angular intervals. As illustrated in FIG. 13, the bolt holes 418 are formed to a depth that extends from the lower end of the outer peripheral protruding portion 404 to the inside of the back yoke portion 403. By forming the bolt holes 418 in the outer peripheral protruding portion 404, a sufficient depth for the bolt holes 418 may be ensured, and the bolt holes 418 will not interfere with a magnetic path in the back yoke portion 403. In the meantime, since the inner peripheral area of the back yoke portion 403 does not have the bolt holes 418, it may be made thinner without risking obstruction of the magnetic path. Therefore, by forming the recess 415 in that area to accommodate the connection board 413, the space on the other side (e.g., lower side in FIG. 13) of the back yoke portion 403 may be effectively utilized.

As illustrated in FIG. 13, the back yoke portion 403 has the opening 401 on the inner side of the teeth 407 in the radial direction. For example, an inner peripheral surface 401a of the opening 401 is located on the inner side of a radial inner end 407a of the teeth 407 in the radial direction. The plurality of lead wires 411, which are drawn out respectively from the plurality of coils 405 described above, are connected to the connection board 413 through the opening 401. A protrusion 419 (e.g., an insulator) provided in the bobbin 409 is arranged between the lead wires 411 and the inner peripheral surface 401a of the opening 401, ensuring insulation between the lead wires 411 and the inner peripheral surface 401a of the opening 401.

FIG. 14 illustrates an example of the structure of the bobbin 409. As illustrated in FIG. 14, the coil 405 is continuously wound in a series alignment around two adjacent bobbins 409A and 409B (e.g., so-called double winding), with a lead wire 411a at one end where the winding starts and a lead wire 411b at the other end where the winding ends. The two bobbins 409A and 409B have protrusions 419a and 419b, respectively, which protrude inward of the opening 401. The protrusions 419a and 419b are made of an insulating material and are formed, for example, in a semi-cylindrical shape. The inner peripheral surface 401a of the opening 401 in the back yoke portion 403 has semi-cylindrical grooves 401b, into which the protrusions 419a and 419b are fitted, respectively. By fitting the protrusions 419a and 419b into the grooves 401b, the protrusions 419a and 419b are positioned correctly, which prevents any circumferential misalignment.

As illustrated in FIG. 14, the lead wire 411a is drawn out from the coil 405 wound around the bobbin 409A along the direction in which the protrusion 419a protrudes, and is connected to a pin 421 (e.g., so-called binding pin) provided at the tip of the protrusion 419a, for example, by a solder. The protrusion 419a has an end surface 423 at the tip thereof on the other side (e.g., lower side in FIG. 14) in the direction of the rotational axis AX3, and the pin 421 is vertically mounted on the end surface 423. Similarly, the lead wire 411b is drawn out from the coil 405 wound around the bobbin 409B along the direction in which the protrusion 419b protrudes, and is connected to the pin 421 provided at the tip of the protrusion 419b, for example, by a solder. The protrusion 419b also has the end surface 423 at the tip thereof on the other side (e.g., lower side in FIG. 14) in the direction of the rotational axis AX3, and the pin 421 is vertically mounted on the end surface 423. A plurality of pins 421 is connected to corresponding terminals 413c of the connection board 413, for example, by a solder. The terminals 413c are formed as notches that are radially recessed outward of the opening 413a of the connection board 413, allowing for the accommodation of the pins 421. As illustrated in FIG. 13, the connection board 413 is positioned such that the surface on one side (e.g., upper side in FIG. 13) in the direction of the rotational axis AX3 abuts against the end surface 423 of the protrusion 419.

In addition, the coil 405 may be wound continuously around three or more bobbins 409, or may be wound individually on each bobbin 409 rather than continuously wound around a plurality of bobbins. Further, an insulating component separate from the protrusion 419a of the bobbin 409 may be provided between the lead wires 411 and the inner peripheral surface 401a of the opening 401. Further, two bobbins 409 may be formed integrally, or may be formed separately and then connected. Further, the bobbin 409 and the protrusion 419 may be formed integrally, or may be formed separately and then connected. Further, the connection board 413 may be arranged with a gap between it and the end surface 423 of the protrusion 419, allowing the surface of the connection board 413 and the end surface 423 of the protrusion 419 to face each other across the gap.

### (5. Effects of Embodiment)

As described above, the rotor 120 of the first motor 101 and the rotor 220 of the second motor 201, according to the present embodiment, include the plurality of magnets 305 arranged in the circumferential direction on the back yoke portion 303, which are constituted with the plurality of first magnets 307 arranged at equal angular intervals in the circumferential direction and the plurality of second magnets 309, each arranged between the first magnets 307 and arranged at a position shifted by the predetermined shift angle θ1 from the center angle of two adjacent first magnets 307 in the circumferential direction. This allows the plurality of magnets 305 on the back yoke portion 303 to be arranged at unequal intervals in the circumferential direction, effectively reducing the cogging torque.

Further, in the present embodiment, when the LCM of the number of slots in the stators 110 and 210 and the number of poles in the rotors 120 and 220 is denoted as the LCM, the shift angle θ1 may be set to {(360°/LCM)/2} or less. In this case, by setting the shift angle θ1 to be equal to or less than half of the one cycle of the cogging torque waveform, e.g., {(360°/LCM)/2}, it is possible to effectively reduce the cogging torque even when it contains a harmonic component.

Further, in the present embodiment, the first magnets 307 and the second magnets 309 may be shaped such that one side edge 305a and the other side edge 305b in the circumferential direction are inclined by a predetermined skew angle θ2 in the same direction with respect to the radial direction DR centered on the rotational axis AX3. In this case, it is possible for the first magnets 307 and the second magnets 309 to bridge the adjacent teeth 407 in the stators 110 and 210, so that even when there is a manufacturing error in the arrangement position of the second magnets 309, the force due to a permeance variation may be prevented. Therefore, shifting the arrangement position of the second magnets 309 by the shift angle θ1 becomes practically feasible.

Further, in the present embodiment, the shift angle θ1 may be set to be less than {(360°/LCM)/2}. This allows a high-frequency component of the cogging torque to be effectively reduced. Therefore, by combining a configuration in which the arrangement position of the second magnets 309 is shifted by the shift angle θ1 and a configuration in which the first magnets 307 and the second magnets 309 have a skewed shape, it is possible to effectively reduce both fundamental and high-frequency components of the cogging torque.

Further, in the present embodiment, the shift angle θ1 may be equal to or greater than 0.75×{(360°/LCM)/2}. In this case, the cogging torque may be made equal to or less than the value of the cogging torque when the shift angle θ1 is {(360°/LCM)/2}. This allows the shift angle θ1 to vary within a suitable range, making it practical to shift the arrangement position of the second magnets 309 by the shift angle θ1.

Further, in the present embodiment, the shift angle θ1 may be near 0.875× {(360°/LCM)/2}. In this case, the shift angle θ1 may be set near the center value of a suitable range {0.75×(360°/LCM)/2≤01≤(360°/LCM)/2}, so that both fundamental and high-frequency components of the cogging torque may be more effectively reduced.

Further, in the present embodiment, the plurality of first magnets 307 and the plurality of second magnets 309 may have the same shape. In this case, as illustrated in FIG. 10, when changing the coefficient K from 0 to 1.0, e.g., when changing the shift angle θ1 from 0 degrees to half of the one cycle of the cogging torque waveform {(360°/LCM)/2}, the value of the cogging torque may gradually decrease to the lowest value and then increase again. This allows the shift angle θ1 to vary within a suitable range, making it practical to shift the arrangement position of the second magnets 309 by the shift angle θ1. Further, manufacturing costs may be reduced since the magnets may be manufactured to have the same shape.

Further, in the present embodiment, the plurality of first magnets 307 and the plurality of second magnets 309 may be shaped such that the outer side edge 305c and the inner side edge 305d in the radial direction are parallel. In this case, the magnet shape may be simplified, making manufacturing easier. Further, it allows for cutting out the magnets 305 from the magnet sheet 315 without waste, improving the yield and reducing the costs.

Further, in the present embodiment, the gap between the first magnets 307 and the second magnets 309 may be shaped such that circumferentially adjacent gap shapes S1 and S2 are mutually dissimilar and do not match even when rotated around the rotational axis AX3. This allows the plurality of magnets 305 on the back yoke portion 303 to be arranged at unequal intervals in the circumferential direction, effectively reducing the cogging torque.

Further, in the present embodiment, the LCM of the number of slots in the stators 110 and 210 and the number of poles in the rotors 120 and 220 may be set to six (6) times or more than the number of poles. In this case, since the shift angle θ1 may be set to be smaller, it is possible to simultaneously apply both a large skew angle θ2 and the unequal interval arrangement of the magnets 305, while minimizing a reduction in the size of the magnets 305.

Further, in the present embodiment, the first motor 101 and the second motor 201 may be arranged at the joint J3 of the transfer robot 10. In this case, the joint J3 of the transfer robot 10 may be driven smoothly since the cogging torque of the first motor 101 and the second motor 201 may be reduced.

Further, as described above, in the stator 110 of the first motor 101 and the stator 210 of the second motor 201 according to the present embodiment, the plurality of coils 405 are arranged on one side of the back yoke portion 403 in the direction of the rotational axis AX3, and the connection board 413 is arranged on the other side in the direction of the rotational axis AX3 relative to the back yoke portion 403. This allows the coils 405, the back yoke portion 403, and the connection board 413 to be arranged in series in the axial direction, so that the outer diameter dimension of the first motor 101 and the second motor 201 may be reduced compared to arranging the connection board 413 radially outward of the back yoke portion 403.

Further, for example, when the connection board 413 is arranged between the coils 405 and the back yoke portion 403, the connection board 413 would reduce the space available for winding the coils 405, thereby decreasing the coil density in the slots. In the present embodiment, the coil density may be increased since the connection board 413 is arranged on the side of the back yoke portion 403 opposite to the side where the coils 405 are mounted.

Further, in the present embodiment, the stator core 400 may have the recess 415 on the other side of the back yoke portion 403 in the direction of the rotational axis AX3, and the connection board 413 may be accommodated in the recess 415. In this case, the axial dimension of the first motor 101 and the second motor 201 may be reduced compared to a case where the connection board 413 is arranged on the other side of the stator core 400. Further, by effectively utilizing the space on the other side of the back yoke portion 403, any occurrence of wasted space may be prevented. Further, the connection board 413 may be protected.

Further, in the present embodiment, the back yoke portion 403 may have the opening 401 on the inner side of the teeth 407 in the radial direction centered on the rotational axis AX3, and the plurality of lead wires 411 may be connected to the connection board 413 through the opening 401. In this case, the lead wires 411 may be wired radially inside the back yoke portion 403 rather than being wired radially outside the back yoke portion 403. Consequently, the outer diameter dimension of the first motor 101 and the second motor 201 may be reduced.

Further, in the present embodiment, the first motor 101 and the second motor 201 may include an insulator made of an insulating material (e.g., the protrusion 419 of the bobbin 409) positioned between the lead wires 411 and the inner peripheral surface 401a of the opening 401. In this case, insulation between the lead wires 411 and the back yoke portion 403 may be ensured.

Further, in the present embodiment, the first motor 101 and the second motor 201 may include the bobbins 409 made of an insulating material, which are mounted on the teeth 407 so that the coils 405 are wound around the outer peripheral surface thereof. The insulator may be formed as the protrusion 419 that protrudes from the bobbin 409 toward the inside of the opening 401. In this case, since the coils 405 are mounted on the teeth 407 through the insulating bobbins 409, it is unnecessary to apply insulation treatment to the surface of the back yoke portion 403 or the teeth 407. Further, using the bobbins 409 facilitates the winding of the coils 405.

Further, in the present embodiment, the lead wires 411 may be drawn out from the coils 405 along the direction in which the protrusion 419 protrudes. In this case, drawing out the lead wires 411 from the coils 405 becomes easier. Further, it is possible to fix the lead wires 411 using the protrusion 419.

Further, in the present embodiment, the groove 401b, into which the protrusion 419 is fitted, may be formed on the inner peripheral surface 401a of the opening 401 in the back yoke portion 403. In this case, by fitting the protrusion 419 of the bobbin 409 into the groove 401b of the back yoke portion 403, the positioning of the bobbin 409 and the protrusion 419 as well as the mounting of the bobbin 409 and the protrusion 419 onto the teeth 407 become easier. Further, this may prevent displacement and vibration of the protrusion 419 and the lead wires 411.

Further, in the present embodiment, the plurality of lead wires 411 may be connected using the connection board 413, the protrusion 419 may have the end surface 423 at the tip thereof on the other side in the direction of the rotational axis AX3, and the connection board 413 may be arranged to come into contact with the end surface 423 of the protrusion 419. In this case, since the connector is configured as the connection board 413, the connection work becomes easier compared to manually connecting the lead wires and others. Further, this facilitates easier connection between the lead wires 411 and the connection board 413, promoting the automation of the connection work. Further, by having the connection board 413 come into contact with the end surface 423 of the protrusion 419, the positioning of the connection board 413 in the direction of the rotational axis AX3 becomes easier.

Further, in the present embodiment, the first motor 101 and the second motor 201 may be arranged at the joint J3 of the transfer robot 10. In this case, the joint J3 of the transfer robot 10 may be reduced in size since the outer diameter dimension of the first motor 101 and the second motor 201 may be reduced.

### (6. Modification)

The disclosed embodiment is not limited to the above description, and may be modified in various ways without departing from the spirit and technical idea.

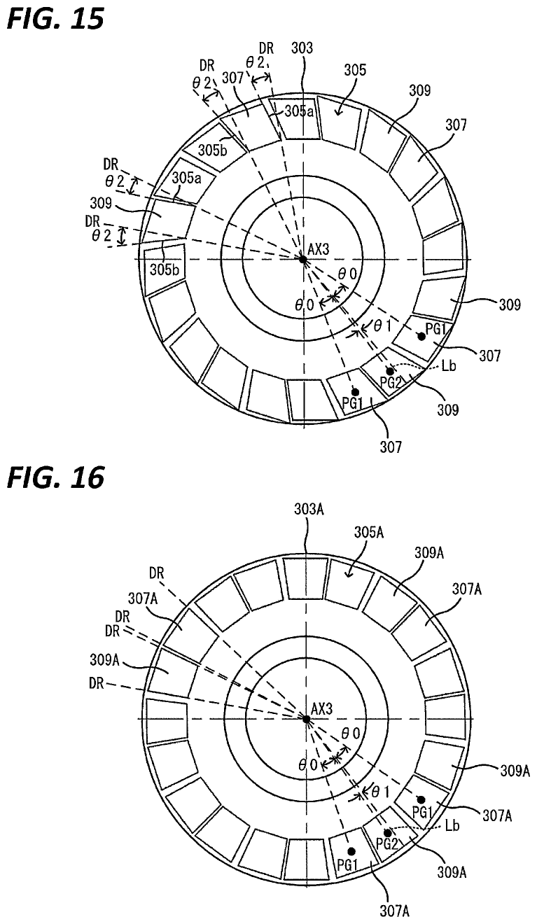

In the above embodiment, as illustrated in FIG. 15, a case was described where the second magnets 309 are arranged at positions shifted by the shift angle θ1, and both the first and second magnets 307 and 309 are skewed at the skew angle θ2 with respect to the radial direction DR, but each magnet does not necessarily have a skewed shape. For example, as illustrated in FIG. 16, a second magnet 309A may be arranged at a position shifted by the shift angle θ1, while both first and second magnets 307A and 309A may be shaped such that one side edge 305a and the other side edge 305b in the circumferential direction extend along the radial direction DR centered on the rotational axis AX3. Even in this case, the cogging torque may be effectively reduced since a plurality of magnets 305A on a back yoke portion 303A may be arranged at unequal intervals in the circumferential direction.

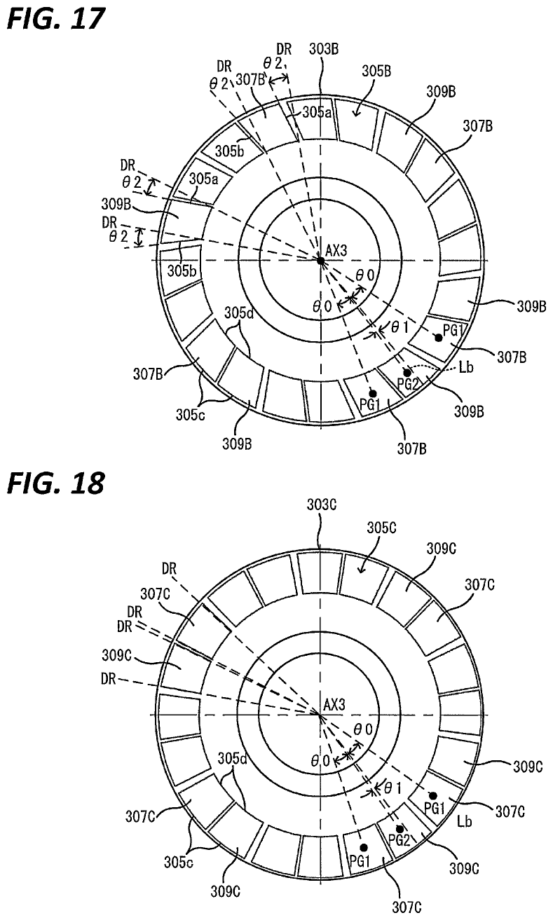

Further, in the above embodiment, a case was described where both the first and second magnets 307 and 309 have the radial outer side edge 305c and the radial inner side edge 305d, which are straight and parallel, but the edges 305c and 305d do not necessarily need to be straight and parallel. For example, as illustrated in FIG. 17, both first and second magnets 307B and 309B may have the radial outer side edge 305c and the radial inner side edge 305d, which have an arc shape centered on the rotational axis AX3. Further, for example, as illustrated in FIG. 18, the outer side edge 305c and the inner side edge 305d may be arc-shaped without incorporating the skew angle θ2 for each magnet. In the shapes illustrated in FIGS. 17 and 18, the outer side edge 305c and the inner side edge 305d are concentric circular arcs. Even in these cases, the cogging torque may be effectively reduced since a plurality of magnets 305B and 305C on back yoke portions 303B and 303C may be arranged at unequal intervals in the circumferential direction.

Further, in the above, a case was described where the configuration of the above embodiment is applied to both the first motor 101 and the second motor 201 provided at the joint J3 of the transfer robot 10, but the configuration may also be applied to either one of the motors. Further, the configuration of the above embodiment may be applied to motors at the joints J1 and J2 of the transfer robot 10 other than the joint J3.

In the above description, when terms such as “vertical,” “parallel,” or “plane” are used, they do not imply strict accuracy. These terms “vertical,” “parallel,” and “plane” mean “substantially vertical,” “substantially parallel,” and “substantially planar,” allowing for design and manufacturing tolerances and errors.

In the above description, when dimensions, sizes, shapes, positions, and others are described as “identical,” “same,” “equal,” or “different,” these descriptions do not imply strict accuracy. These terms “identical,” “same,” “equal,” and “different” mean “substantially identical,” “substantially the same,” “substantially equal,” and “substantially different, allowing for design and manufacturing tolerances and errors.

In addition to those already described above, the methods according to the above embodiment and respective modifications may be used in appropriate combinations. In addition, although not individually exemplified, the above-described embodiment and respective modifications may be implemented with various changes within the scope of the intended purpose without deviating from the spirit thereof.

From the foregoing, it will be appreciated that various embodiments of the present disclosure have been described herein for purposes of illustration, and that various Modifications may be made without departing from the scope and spirit of the present disclosure. Accordingly, the various embodiments disclosed herein are not intended to be limiting, with the true scope and spirit being indicated by the following claims.

What is claimed is:

1. An axial gap motor comprising:
a rotor that rotates about a rotational axis;
a stator that faces the rotor in a direction of the rotational axis;
a first back yoke provided on either the rotor or the stator; and
a plurality of magnets arranged on the first back yoke along a circumferential direction around the rotational axis,
wherein the plurality of magnets include:
a plurality of first magnets arranged at an equal angular interval in the circumferential direction; and
a plurality of second magnets each arranged between the plurality of first magnets and arranged at a position shifted by a predetermined first angle from a center angle of two adjacent first magnets in the circumferential direction.

2. The axial gap motor according to claim 1, wherein, when the first angle is θ and a least common multiple of a number of slots in the stator and a number of poles in the rotor is LCM, the first angle θ satisfies θ≤(360°/LCM)/2.

3. The axial gap motor according to claim 1, wherein the first magnets and the second magnets are shaped such that one side edge and a remaining side edge thereof in the circumferential direction are inclined by a predetermined second angle in the same direction with respect to a radial direction centered on the rotational axis.

4. The axial gap motor according to claim 3, wherein, when the first angle is θ and the least common multiple of a number of slots in the stator and a number of poles in the rotor is LCM, the first angle θ satisfies θ<(360°/LCM)/2.

5. The axial gap motor according to claim 4, wherein, when θ≥0.75×{(360°/LCM)/2}, a value of a cogging torque generated between the rotor and the stator when the rotor is rotated around the rotational axis is equal to or less than the value of the cogging torque when the θ is (360°/LCM)/2.

6. The axial gap motor according to claim 5, wherein the θ is near 0.875×{(360°/LCM)/2}.

7. The axial gap motor according to claim 5, wherein the plurality of first magnets and the plurality of second magnets have the same shape.

8. The axial gap motor according to claim 5, wherein the plurality of first magnets and the plurality of second magnets have a shape with parallel outer side and inner side edges in the radial direction.

9. The axial gap motor according to claim 1, wherein a gap shape between the first magnet and the second magnet is dissimilar to a gap shape adjacent in the circumferential direction and does not match even when rotated around the rotational axis.

10. The axial gap motor according to claim 2, wherein the LCM is six (6) times or more than the number of poles.

11. The axial gap motor according to claim 1, further comprising:
a second back yoke provided on a remaining one of the rotor and the stator;
a plurality of teeth protruding from the second back yoke toward one side in the direction of the rotational axis;
a plurality of coils mounted on the plurality of teeth; and
a connector arranged on a remaining side in the direction of the rotational axis relative to the second back yoke and serving to connect a plurality of lead wires drawn out from the plurality of coils.

12. A robot with an axial gap motor arranged at a joint,
wherein the axial gap motor comprises:
a rotor that rotates about a rotational axis;
a stator that faces the rotor in a direction of the rotational axis;
a first back yoke provided on either the rotor or the stator; and
a plurality of magnets arranged on the first back yoke along a circumferential direction around the rotational axis,
wherein the plurality of magnets include:
a plurality of first magnets arranged at an equal angular interval in the circumferential direction; and
a plurality of second magnets each arranged between the plurality of first magnets and arranged at a position shifted by a predetermined first angle from a center angle of two adjacent first magnets in the circumferential direction.

13. A robot system comprising:
the robot according to claim 12; and
a control device that controls an operation of the robot.
